(19) United States
(12) Patent Application Publication
(10) Pub. No.: US 2025/0372987 A1
(43) Pub. Date: Dec. 4, 2025

(54) POWER SUPPLY DEVICE FOR SUPPLYING POWER TO A PULL-OUT ELEMENT

(71) Applicants: Maximilian ROSSMANN, Oberreute (DE); Julian PONTNER, Hard (AT); Maximilian STOSS, Hohenems (AT)

(72) Inventors: Maximilian ROSSMANN, Oberreute (DE); Julian PONTNER, Hard (AT); Maximilian STOSS, Hohenems (AT)

(21) Appl. No.: 19/302,990

(22) Filed: Aug. 18, 2025

Related U.S. Application Data
(63) Continuation of application No. PCT/AT2024/060062, filed on Feb. 20, 2024.

(30) Foreign Application Priority Data
Feb. 24, 2023 (AT) A 50132/2023

(51) Int. Cl. H02G 3/18; A47B 88/919; H02G 3/08

(52) U.S. Cl. CPC H02G 3/18; A47B 88/919; H02G 3/081; A47B 2220/0091

(57) ABSTRACT

A power supply device includes a pull-out guide for movably mounting the pull-out element on a furniture body. The pull-out guide has a body rail mounted on the furniture body, and a drawer rail to be connected to the pull-out element and movable relative to the body rail. A power outlet device is to be connected to the pull-out element, and a cable guide is to be connected to the pull-out guide. The pull-out guide or the pull-out element is connected to a drive device to drive the drawer rail or the pull-out element. A driver detachably fastened to the pull-out guide by an interface to cooperate with the drive device to transmit a force from the drive device to the pull-out guide or the pull-out element. The cable guide and the driver form a common structural unit to be detachably fastened to the interface of the pull-out guide.

The present application is a continuation of International Application PCT/AT2024/060062 filed on Feb. 20, 2024. Thus, all of the subject matter of International Application PCT/AT2024/060062 is incorporated herein by reference.

### BACKGROUND OF THE INVENTION

The invention relates to a power supply device, an arrangement with at least one pull-out element, preferably a drawer or a tray, and at least one such power supply device, as well as a method for mounting such an arrangement on at least one furniture body.

WO 2022/051786 A2 discloses a power supply device for pull-out elements.

However, this solution is not suitable for pull-out guides where drive devices are to be used to influence the movement of the pull-out guide or the pull-out element, since the placement of the cable guide prevents the attachment of a drive device to the pull-out guide.

### SUMMARY OF THE INVENTION

The object of the present invention is to at least partially eliminate the disadvantages known from the prior art and to provide a power supply device which is improved compared to the prior art and which in particular is compatible with drive devices for influencing the movement of the pull-out guide. Furthermore, an arrangement with at least one pull-out element and at least one power supply device improved in this way as well as a method for mounting such an arrangement on at least one furniture body are to be provided.

Accordingly, the pull-out guide or pull-out element is connectable or connected to at least one drive device with which the drawer rail or the pull-out element to be connected thereto can be driven relative to the body rail, and the power supply device comprises at least one driver which can be detachably fastened to the pull-out guide via at least one interface and is designed to interact with the drive device in order to transmit a force from the drive device to one of the rails of the pull-out guide or to the pull-out element. The cable guide and the driver form a common structural unit which can be detachably fastened to the interface of the pull-out guide.

This makes it possible to arrange the cable guide offset from the driver, which interacts with the drive device. At the same time, no additional interface for cable routing needs to be provided for the pull-out guide. Rather, the interface of the pull-out guide fulfills a dual function, namely the attachment of the driver and the attachment of the cable guide. This results in a space-saving and cost-effective design, which at the same time allows the use of technically advantageous pull-out guides compared to the prior art.

The arrangement according to the invention with at least one pull-out element, preferably a drawer or a tray, has at least one power supply device according to the invention, wherein the pull-out element is connected in a position of use, preferably on a longitudinal side, to the drawer rail of the at least one pull-out guide.

The method according to the invention for mounting at least one arrangement according to the invention on at least one furniture body comprises the following method steps, preferably in the specified chronological order: the at least one pull-out guide is mounted on the furniture body via the body rail, the at least one driver and the at least one cable guide are detachably fastened to the interface of the pull-out guide, optionally at least one drive device is connected to the pull-out guide or the pull-out element, the at least one power outlet device is connected to the pull-out element and the at least one pull-out element is connected to the drawer rail of the pull-out guide.

### BRIEF DESCRIPTION OF THE DRAWINGS

Further details and advantages of the invention will be explained in more detail below with reference to the drawings, in which:

FIGS. 1, 2 show a first exemplary embodiment of an arrangement with a tray and a power supply device according to a first exemplary embodiment in a perspective view, wherein in FIG. 2 the power outlet device is dismantled,

FIGS. 3, 4 show the configuration shown in FIGS. 1 and 2 without a base (FIG. 3), with the section 87 shown enlarged, and from the underside (FIG. 4),

FIG. 5 shows the first exemplary embodiment of the power supply device in an exploded view,

FIG. 6 shows the common structural unit consisting of cable guide and driver in a plan view from above,

FIG. 7 shows a drive device in a highly simplified schematic representation,

FIGS. 8, 9 show a second exemplary embodiment of a current conducting device in a perspective view (FIG. 8), and in an exploded view (FIG. 9),

FIG. 10, 11 show the current conducting device according to the first exemplary embodiment in the mounted state on a base with a first thickness in a cross-sectional view (FIG. 10) and in a perspective view (FIG. 11),

FIGS. 12, 13 show the current conducting device according to the first exemplary embodiment in the mounted state on a base with a first thickness in a cross-sectional view (FIG. 12) and in a perspective view (FIG. 13),

FIG. 14 shows a second exemplary embodiment of an arrangement with a drawer and a power supply device according to a second exemplary embodiment in a perspective view,

FIG. 15 shows a third exemplary embodiment of a current conducting device in an exploded view,

FIGS. 16-19 show the current conducting device according to the second exemplary embodiment in the mounted state on a base with a first thickness in a perspective view (FIG. 16), without base (FIG. 17) and in two different cross-sectional views (FIGS. 18, 19),

FIGS. 20-23 show the current conducting device according to the second exemplary embodiment in the mounted state on a base with a second thickness in a perspective view (FIG. 20), without a base (FIG. 21) and in two different cross-sectional views (FIGS. 22, 23),

FIGS. 24, 25 show the current conducting device according to the second exemplary embodiment in the mounted state on a base with a first thickness (FIG. 24) and with a second thickness (FIG. 25), each in a further cross-sectional view,

FIGS. 26-29 show another exemplary embodiment of a power outlet device in a perspective view (FIG. 26) and in exploded views (FIGS. 27-29) from different viewing directions, and

FIGS. 30, 31 show another exemplary embodiment of a power outlet device in a perspective view (FIG. 30) and in an exploded view (FIG. 31).

### DETAILED DESCRIPTION OF THE INVENTION

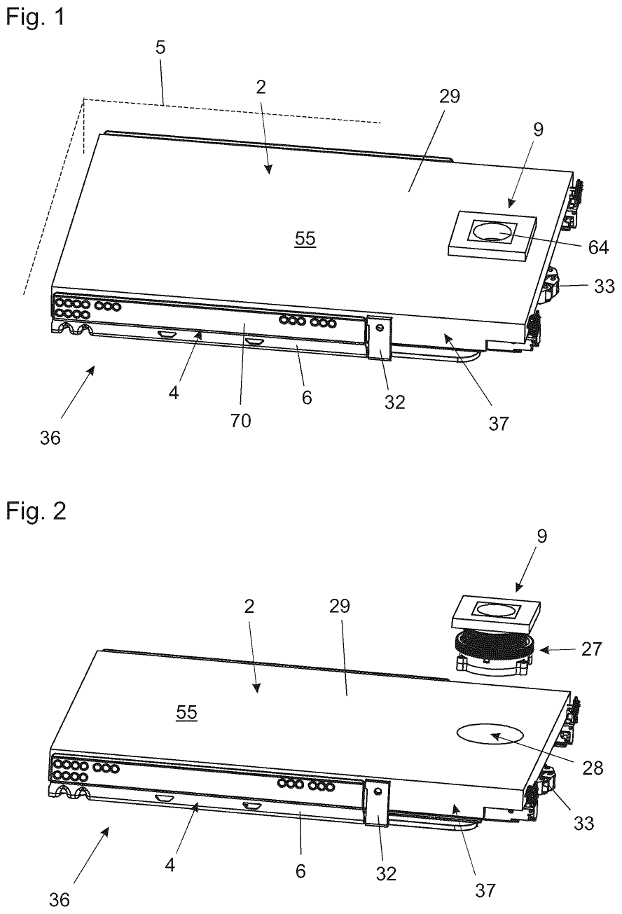

FIGS. 1 and 2 show an arrangement 36 with at least one pull-out element 2, which in the illustrated exemplary embodiment is designed as a tray.

The arrangement 36 comprises at least one power supply device 1, details of the power supply device 1 being shown in the following FIGS. 2 to 6.

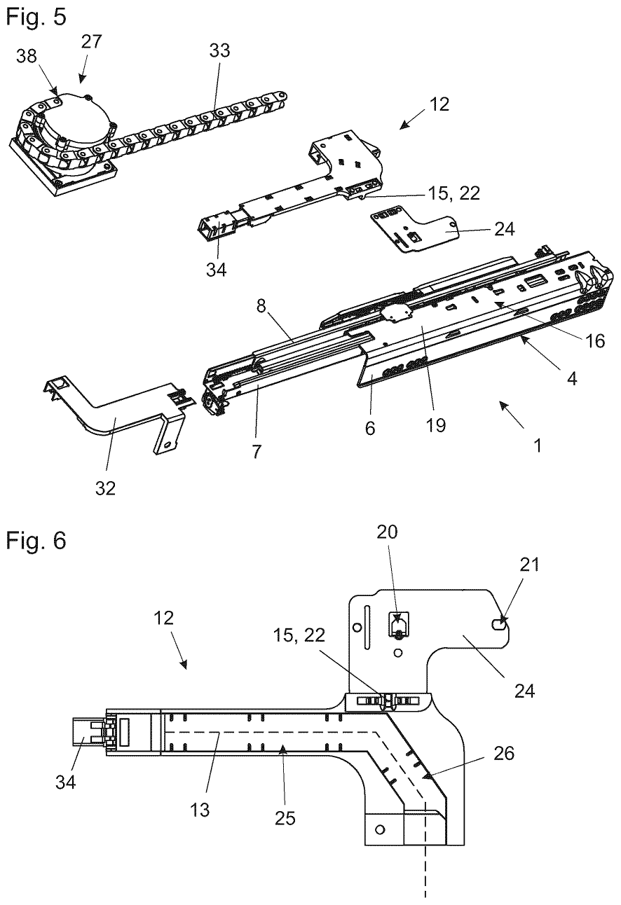

The power supply device 1 serves to supply power to the at least one pull-out element 2, preferably with 230 V, and comprises at least one pull-out guide 4 for the movable mounting of the pull-out element 4 on a furniture body 5, wherein the pull-out guide 4 has a body rail 6 to be mounted on the furniture body 5 and a drawer rail 7 to be connected to the pull-out element 2, wherein the body rail 6 and the drawer rail 7 are mounted so as to be movable relative to one another, preferably wherein at least one central rail 8 is arranged between the body rail 6 and the drawer rail 7 (see also FIG. 5).

The pull-out element 2 is connected in a position of use, preferably on a longitudinal side 37, to the drawer rail 7 of the at least one pull-out guide 4. In the illustrated exemplary embodiment, a pull-out guide 4 is arranged on each of the two opposite longitudinal sides 37 of the pull-out element 2.

Power supply device 1 comprises at least one power outlet device 9, preferably a socket, connected to the pull-out element 2. Consumers such as a food processor, a hairdryer or a charging cable can be connected to this socket.

The pull-out element 2 has at least one base 29 which is horizontally aligned in the position of use of the pull-out element 2 and in which at least one, preferably cylindrical, opening 28 is formed.

In the illustrated exemplary embodiment, the at least one power outlet device 9 is arranged at least in regions within the base opening 28, i.e. it is a “recessed socket”.

The power outlet device 9 can be supplied with energy as follows. At least one current conducting device 27 is fastened to and/or in the base opening 28 in order to conduct current through the base opening 28 to the power outlet device 9.

The current conducting device 27 has at least one holder 46 to be connected to an underside 45 of the base 29 of the pull-out element 2 and a bridging device 48 to be arranged in the base opening 28, wherein a distance 51 of an upper side of the bridging device 48 relative to the holder 46 is adjustable in order to adapt the current conducting device 27 to different thicknesses of the base 29 of the pull-out element 2, preferably between 5 mm and 30 mm.

In the illustrated embodiment, the bridging device 48 has at least one cylindrical body with an external thread 53, on which the holder 46, designed as a rotating part with an internal thread, is rotatably mounted.

At least one cable guide 12 is provided, which is preferably to be connected to the pull-out guide 4 and is designed to guide at least one power cable 13 to the power outlet device 9 (see also FIG. 6).

It is advisable that the cable guide 12, as in the case shown, comprises at least one groove 25 into which the at least one power cable 13 to be guided can be inserted, and at least one redirection device 26 which redirects the at least one power cable 13 to be guided by at least 90°.

At least one drag chain 33 is advantageously arranged between the cable guide 12 and the current conducting device 27, which drag chain 33 is designed to guide the at least one power cable 13 in a plane below the pull-out element 2 during a movement of the pull-out element 2 between a closed position and an open position. The term “drag chain” is to be interpreted broadly in the sense of an energy guide system that guides and simultaneously protects flexible cables and/or lines. However, the drag chain does not necessarily have to be made up of chain links.

The drag chain 33 can be connected to the current conducting device 27 at a connection point 38.

At least one plug-in device 34 can be provided, which is arranged stationary, preferably on the body rail 6, and via which the power supply device 1 can be connected to a stationary power source 35. In the case shown, the plug-in device 34 is arranged on the cable guide 12.

The plug-in device 34 may be a country-specific adapter.

The plug-in device 34 and the stationary power source 35 can be connected via at least one power cable 89, which can be a country-specific cable (see FIG. 4).

Furthermore, the power supply device 1 can comprise at least one cable holder 32, which can be detachably and/or frontally connected to the body rail 6. For this purpose, a plug connection can be provided, for example.

Alternatively or additionally, the power supply device 1 can have at least one switch-off device which has at least one sensor for detecting a closed position of the pull-out guide 4 or the pull-out element 2, 3 and at least one switching element with which the power supply can be interrupted depending on a signal from the sensor.

Preferably, the components of the power supply device 1 can be attached to the pull-out guide 4 and/or to the pull-out element 2, 3 without tools, which allows for retrofitting.

A further significant advantage of the power supply device 1 shown is that the components are largely arranged in a space-saving manner below the base 29 of the pull-out element 2, 3, which enables a cost-effective construction.

The cable guide 12 can be fastened to the pull-out guide 4 as follows:

The power supply device 1 can have at least one drive device 14 to be connected to the pull-out guide 4 or the pull-out element 2, 3, with which the drawer rail 7 or the pull-out element 2, 3 to be connected thereto can be driven relative to the body rail 6, and at least one driver 15 which can be detachably fastened to the pull-out guide 4 via at least one interface 16 and is designed to cooperate with the drive device 14 in order to transmit a force from the drive device 14 to one of the rails of the pull-out guide 4 or the pull-out element 2, 3, wherein the cable guide 12 and the driver 15 form a common structural unit which can be detachably fastened to the interface 16 of the pull-out guide 4.

It is advisable that the interface 16 is arranged on an underside 19 of the body rail 6 which faces downwards in the position of use of the pull-out guide 4 and/or has at least one locking device 20 and/or suspension device 21 with which the common structural unit can be locked and/or suspended on the pull-out guide 4.

In the embodiment shown in FIG. 6, both a suspension device 21, via which the common structural unit can be suspended on the body rail 6, and a locking device 20, via which the structural unit can be locked on the body rail 6, preferably in the course of a rotational movement about a vertical axis, are provided.

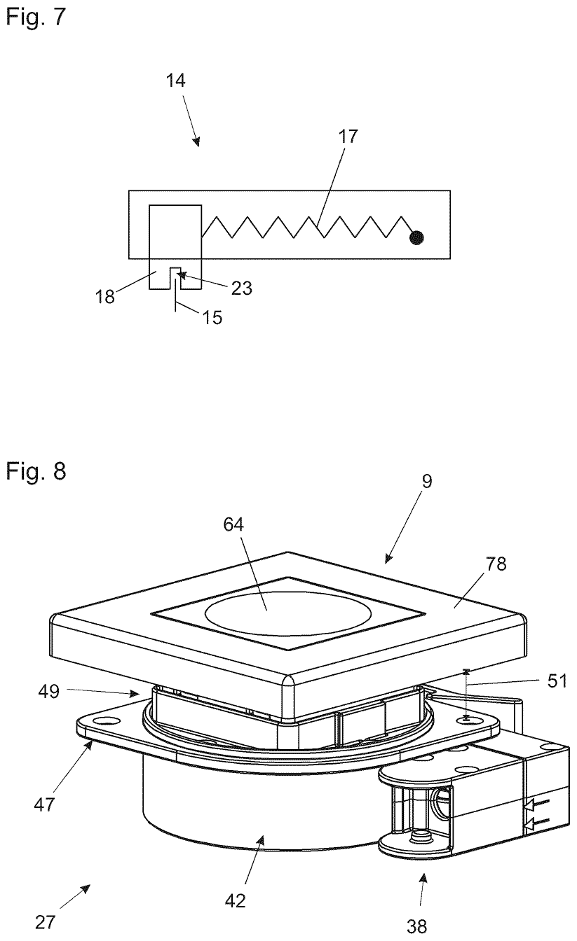

The driver 15 comprises at least one protruding pin 22 or bolt, which can be inserted into an opening 23 of the drive device 14 (see also FIG. 7).

The common structural unit may comprise a substantially flat holding plate 24 which is connectable or connected to the driver 15, the cable guide 12 and/or the interface 16 of the pull-out guide 4.

In this and the other illustrated exemplary embodiments, the arrangement 36 can be mounted on at least one furniture body 5 (indicated schematically in FIG. 1) as follows: the at least one pull-out guide 4 is mounted on the furniture body 5 via the body rail 6, preferably on a holding web 70 of the body rail 6, the at least one power outlet device 9, 10, 11 is connected to the pull-out element 2, 3, and the at least one pull-out element 2, 3 is connected to the drawer rail 7 of the pull-out guide 4.

Optionally, the following method steps can be provided alone or in combination: the at least one driver 15 and the at least one cable guide 12 are detachably fastened to the interface 16 of the pull-out guide 4, the at least one drive device 14 is connected to the pull-out guide 4 or the pull-out element 2, 3, the at least one current conducting device 27 is fastened to and/or in the base opening 28, and/or the at least one power outlet device 9, 10, 11 is connected to the pull-out element 2, 3 by means of at least one holding device 30, 31 on and/or in and/or above the base opening 28.

FIG. 7 shows a drive device 14 in a highly simplified schematic representation.

The drive device 14 comprises at least one energy accumulator 17, preferably at least one spring device, and at least one drive element 18 which can be driven thereby and which can be coupled to the driver 15.

The drive device 14 can be designed as an ejection device in order to eject the drawer rail 7 or the pull-out element 2, 3 to be connected thereto relative to the body rail 6 from a closed position towards an open position.

The drive device 14 can alternatively or additionally be designed as a retraction device 71 which interacts with an actuator 72.

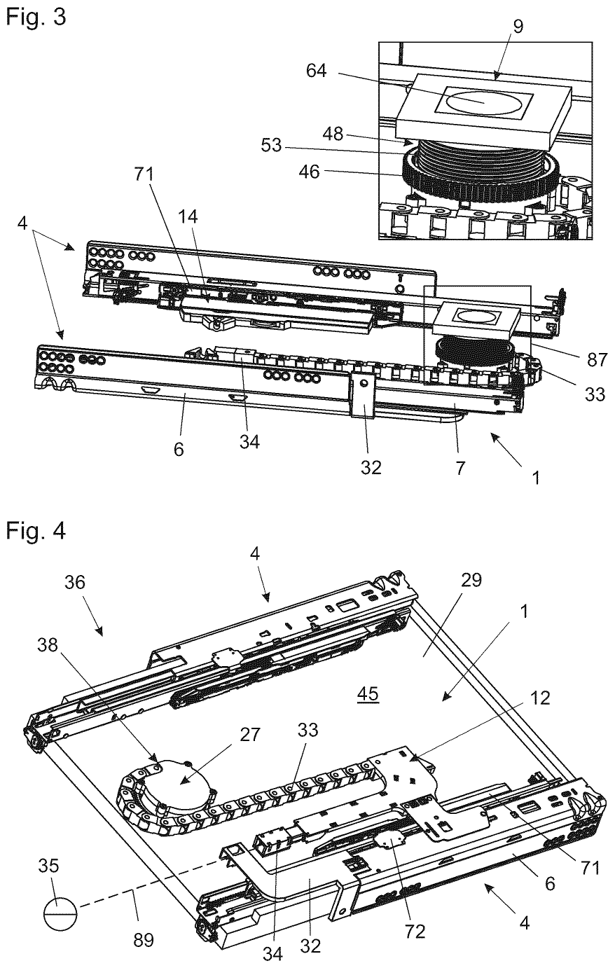

In the embodiment shown in FIG. 3, both an ejection device 14 and a retraction device 71 are provided. These can be designed modularly or in a common unit.

The cable guide 12 can form a common structural unit with the driver 15 and/or with the actuator 72.

FIGS. 8 to 13 show a further embodiment of a current conducting device 27.

The current conducting device 27 has at least one connection point 38 for at least one power cable 13 and/or at least one drag chain 33, preferably wherein the at least one connection point 38 comprises at least one plug connection 39 and/or is arranged in a plane parallel to the base 29 of the pull-out element 2, 3.

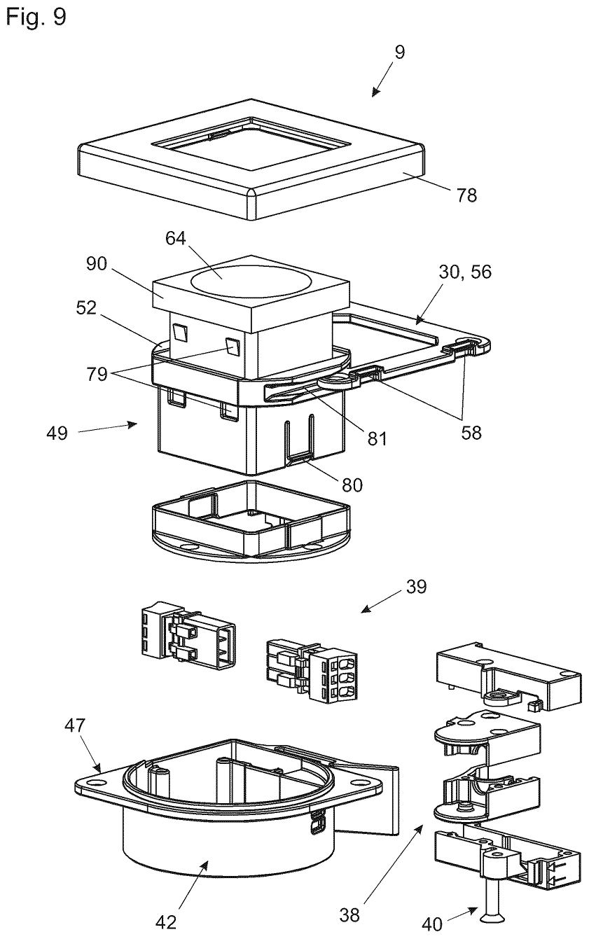

A plug connection 39 (see FIG. 9) facilitates the mounting of the pull-out element 2, 3 by allowing the pull-out element 2 to be placed on the drawer rail 7 and then the current conducting device 27 to be connected to the power cable 13 and/or the drag chain 33.

At least one adjustment device 40 is provided, with which a position of the connection point 38 relative to a base body 42 of the current conducting device 27 and/or a distance 44 of the connection point 38 relative to an underside 45 of the base 29 of the pull-out element 2, 3 can be adjusted.

This has the advantageous technical effect that the current conducting device 27 can be adjusted to different pull-out guides 4. Different pull-out guides 4 can differ in their construction height, in particular due to a distance between the underside of the body rail 6 and a support web of the drawer rail 7.

In the illustrated embodiment, the adjusting device 40 comprises an adjusting screw with which the connection point 38 can be adjusted in the vertical direction relative to the base body 42 (see FIG. 9). To facilitate adjustment, a marking may be provided which, for example, includes at least two arrows.

At least one holding device 30 is provided, which is designed to hold a power outlet device 9 on and in an opening 28 in a base 29 of the pull-out element 2, 3, which is horizontally aligned in the position of use of the pull-out element 2, 3.

The at least one holding device 30 is arranged or can be arranged on the current conducting device 27 as in the case shown, preferably wherein the holding device 30 is arranged displaceably on the current conducting device 27.

A groove 81 can be provided for sliding mounting.

The holding device 30 can facilitate the mounting of the current conducting device 27 by securing the current conducting device 27 inserted from above into the base opening 28 against further slipping downwards.

The holding device 30 comprises at least one holding bracket to be connected, preferably screwed, to an upper side 55 of the base 29 of the pull-out element 2, 3.

The holding device 30 is fork-shaped at least in some regions and surrounds the base opening 28 in the mounting position at least in some regions.

The power outlet device 9 can be connected to the holding device 30 via at least one latching connection 58 and/or at least one screw connection 59 and/or can be pushed onto the holding device 30.

In the illustrated embodiment, a locking connection 58 is provided which is effective between a frame 78 of the power outlet device 9 and the holding device 30. A central body 90, which is arranged in the assembled position within the frame 78, can be pushed from above onto the holding device 30 and on a bridging device 49 connectable or connected thereto and can be secured by a snap connection 79.

The current conducting device 27 has at least one holder 47 to be connected to an underside 45 of the base 29 of the pull-out element 2, 3 and a bridging device 49 to be arranged in the base opening 28, wherein a distance 51 of an upper side 52 of the bridging device 49 relative to the holder 47 is adjustable in order to adapt the current conducting device 27 to different thicknesses of the base 29 of the pull-out element 2, 3, preferably between 5 mm and 30 mm.

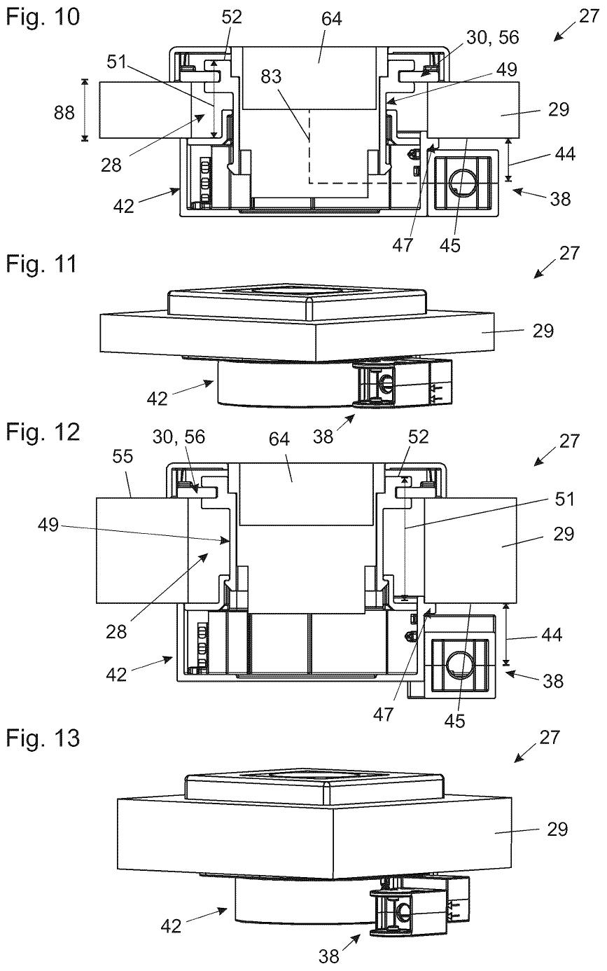

The bridging device 49 can be slidably mounted in and/or on the holder 47. FIGS. 10 and 12 show, by way of example, two different positions of the bridging device 49 relative to the holder 47 depending on two different thicknesses 88 of the base 29.

In order to prevent the holder 47 or the base body 42 on which the holder 47 is formed from slipping downwards during mounting, the bridging device 49 can have at least one retaining device 80 which, for example, comprises a resilient hook.

On the upper side 52 of the bridging device 49, a counter-holder 56 is arranged or can be arranged to be connected to an upper side 55 of the base 29 of the pull-out element 2, 3.

In the illustrated embodiment, the current conducting device 27 is secured, preferably screwed, to the base 29 from below via the holder 47 and from above via the counterholder 56.

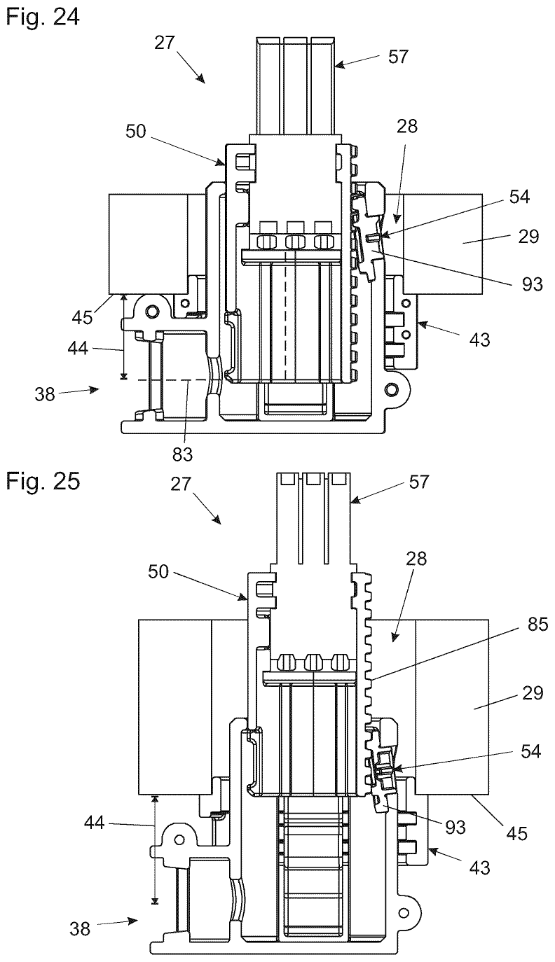

For the sake of clarity, electrical wiring is not shown in the figures. By way of example, a current conductor 83 is indicated in FIGS. 10 and 24, which electrically connects the connection point 38 to the power outlet device 9 or a plug-in device 57.

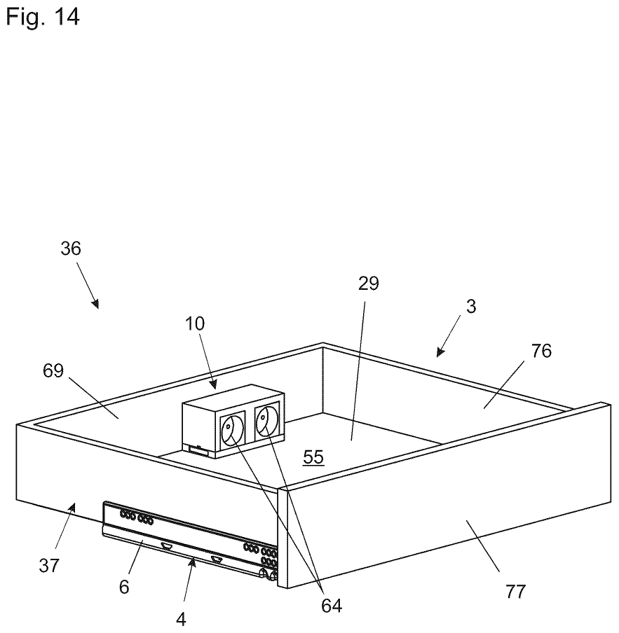

FIG. 14 shows a further embodiment of an arrangement 36 with a pull-out element 3 designed as a drawer and a power supply device 1 according to a further embodiment.

The pull-out element 3 is connected in a position of use, preferably on a longitudinal side 37, to the drawer rail 7 of the at least one pull-out guide 4.

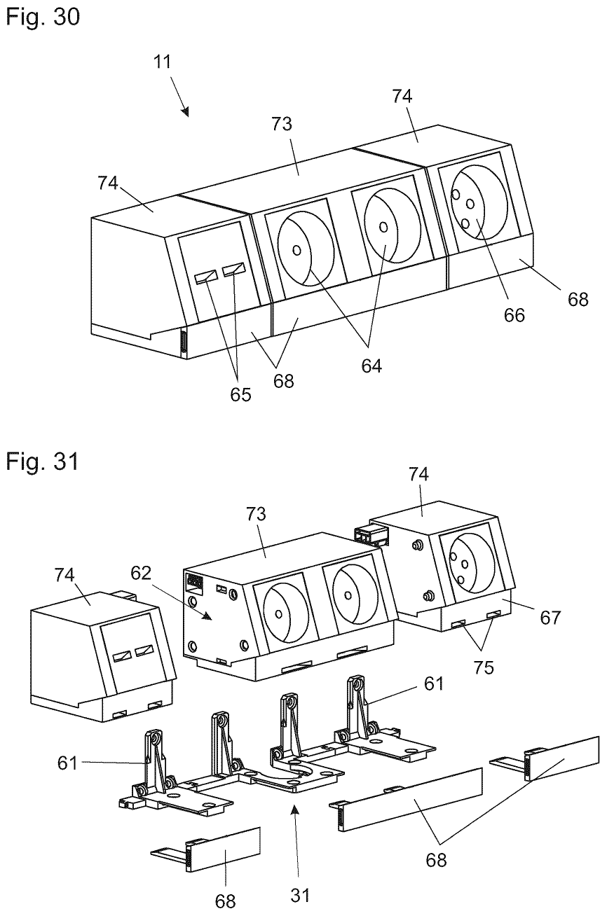

The pull-out element 3 has at least one rear wall 69 oriented substantially vertically to the base 29. At least one power outlet device 10 or 11 (cf. FIGS. 30, 31) is arranged above the base opening 28, in a plane parallel to the rear wall 69 and outside the rear wall 69.

Alternatively or additionally, the pull-out element 3 can also have a power outlet device 9 sunk into the base 29, as shown, for example, in the previous figures.

The pull-out element 3 can have two opposite side walls 76 and a front wall 77.

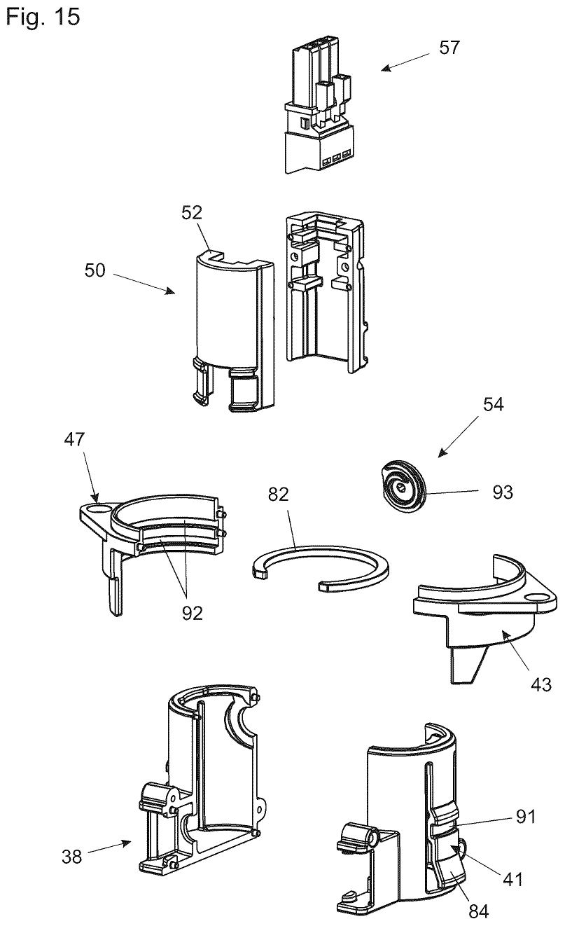

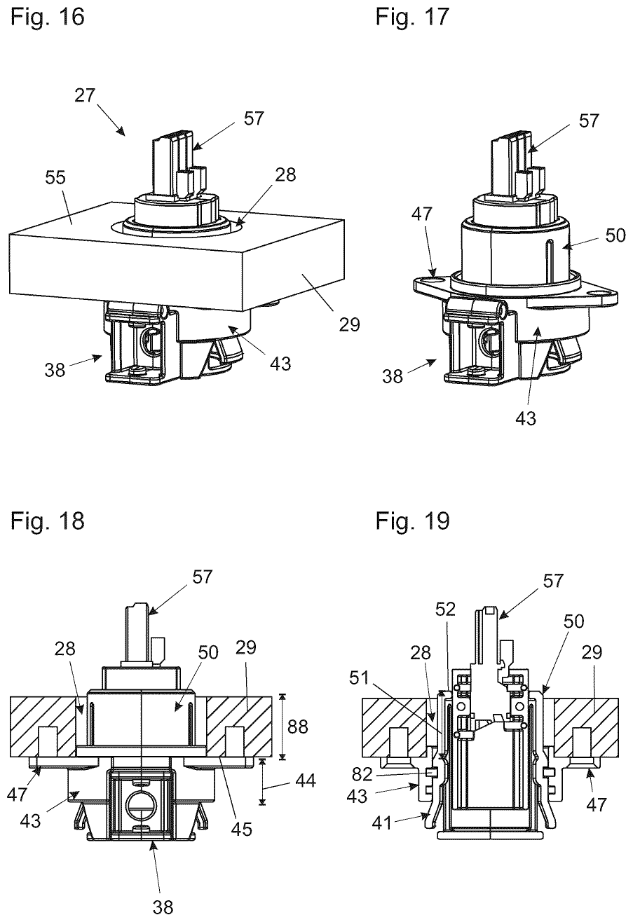

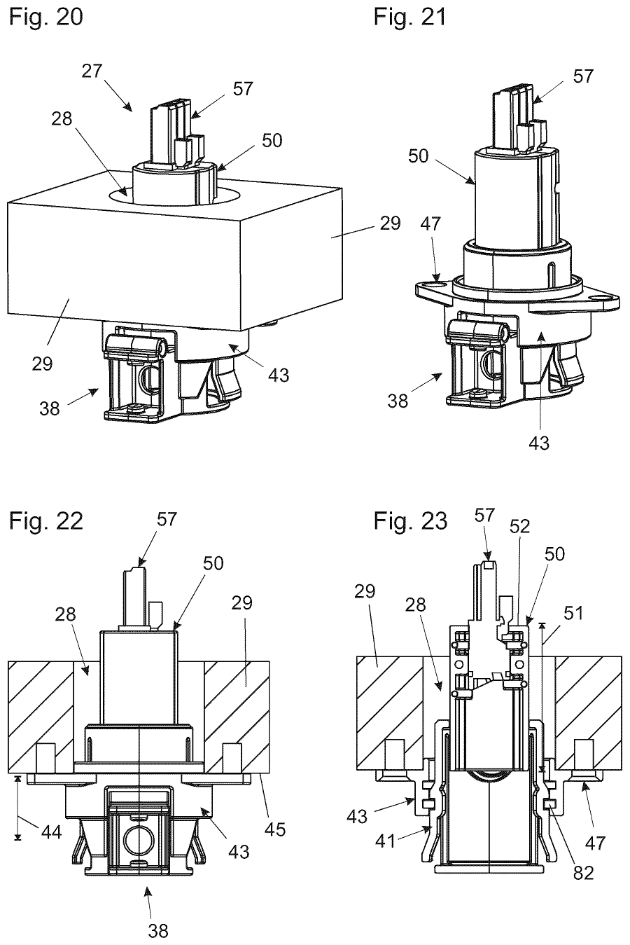

FIGS. 15 to 25 show a further embodiment of a current conducting device 27.

The current conducting device 27 has at least one connection point 38 for at least one power cable 13 and/or at least one drag chain 33, preferably wherein the at least one connection point 38 comprises at least one plug connection 39 and/or is arranged in a plane parallel to the base 29 of the pull-out element 2, 3.

At least one adjustment device 41 is provided, with which a position of the connection point 38 relative to a base body 43 of the current conducting device 27 and/or a distance 44 of the connection point 38 relative to an underside 45 of the base 29 of the pull-out element 2, 3 can be adjusted.

As in the case shown, the adjustment device 41 can have a locking element 82 mounted on a preferably resilient actuating lever 84 in a groove 91, which can be locked into corresponding recesses 92 (cf. FIGS. 19 and 23).

The current conducting device 27 has at least one holder 47 to be connected, preferably screwed, to an underside 45 of the base 29 of the pull-out element 2, 3 and a bridging device 50 to be arranged in the base opening 28, wherein a distance 51 of an upper side 52 of the bridging device 50 relative to the holder 47 is adjustable in order to adapt the current conducting device 27 to different thicknesses of the base 29 of the pull-out element 2, 3, preferably between 5 mm and 30 mm.

At least one adjustment device 54 is provided with which a position of the bridging device 50 relative to the holder 47 can be adjusted. The adjusting device 54 may, for example, comprise a rotatably mounted worm wheel 93 which interacts with a toothing 85 (cf. FIGS. 24 and 25).

The current conducting device 27 has at least one plug-in device 57, via which the power outlet device 10, 11 can be brought into electrically conductive contact with the current conducting device 27, preferably wherein the plug-in device 57 protrudes from the base opening 28 over the upper side 55 of the base 29 of the pull-out element 2, 3 in the assembled position of the current conducting device 27.

The at least one plug-in device 57 facilitates the mounting and removal of the pull-out element 2, 3.

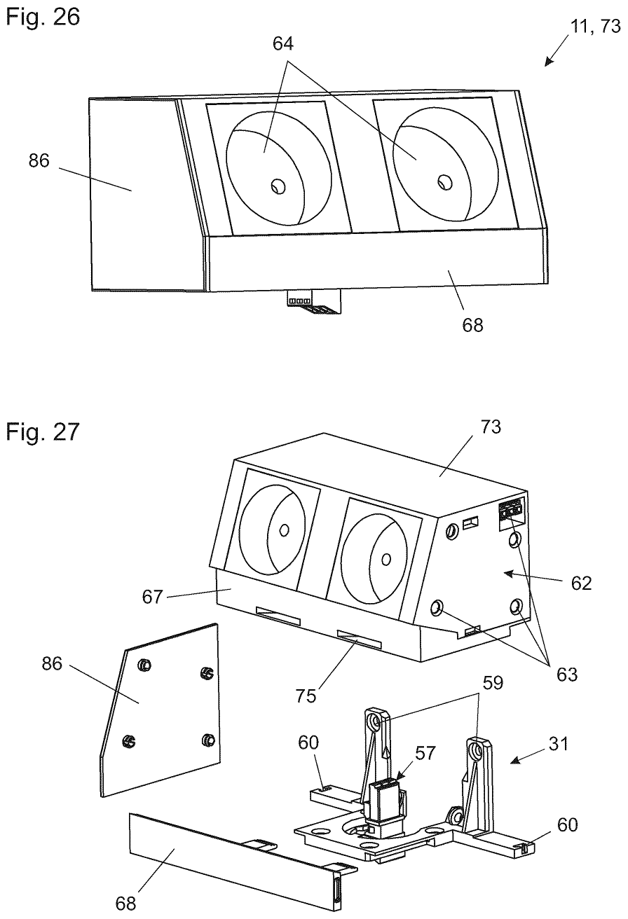

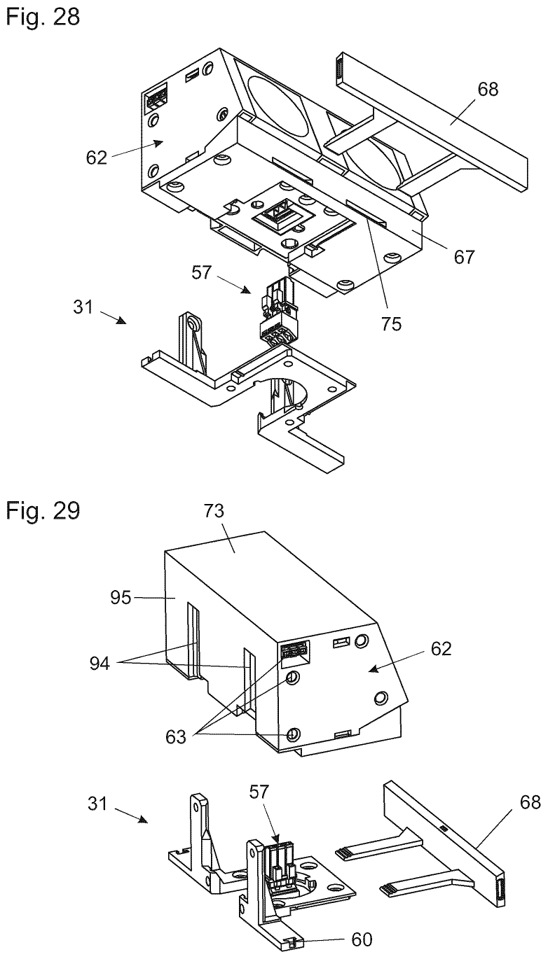

FIGS. 26 to 29 and FIGS. 30 and 31 show further exemplary embodiments of a power outlet device 11.

At least one holding device 31 is provided, which is designed to hold the power outlet device 11 on and above an opening 28 in a base 29 of the pull-out element 2, 3, which is horizontally aligned in the position of use of the pull-out element 2, 3.

The holding device 31 comprises at least one holding bracket to be connected, preferably screwed, to an upper side 55 of the base 29 of the pull-out element 2, 3.

The holding device 31 is fork-shaped at least in some regions and surrounds the base opening 28 in the mounting position at least in some regions.

The power outlet device 11 can be connected to the holding device 31 via at least one screw connection 59 and can be pushed onto the holding device 31. For this purpose, guides 94 are arranged on the power outlet device 11, preferably on a rear side 95.

The holding device 31 has at least one interface 60 for connection to at least one further holding device 61 for at least one further power outlet device.

The power outlet device 11 has at least one interface 63, preferably arranged on a side surface 62, for connecting at least one further power outlet device, preferably wherein the power outlet devices differ from one another by a shape of a power plug receptacle 64, 65, 66 (cf. FIG. 30). For example, it can be a USB plug socket or a 230V plug socket commonly used in German-speaking countries.

In the embodiment according to FIGS. 30, 31, a central basic module 73 is provided, to which additional modules 74 are attached laterally.

The interface 63 can be covered by a cover 86.

The power outlet device 11 can have at least one interface 75 for mounting a logo plate 68, preferably arranged near the base 29 of the pull-out element 2, 3 and/or on an end face 67.

1. A power supply device for supplying power to at least one pull-out element, preferably a drawer or a tray, comprising:
at least one pull-out guide for the movable mounting of the pull-out element on a furniture body, wherein the pull-out guide has a body rail to be mounted on the furniture body and a drawer rail to be connected to the pull-out element, wherein the body rail and the drawer rail are mounted so as to be movable relative to one another, preferably wherein at least one central rail is arranged between the body rail and the drawer rail,
at least one power outlet device, preferably a socket, to be connected to the pull-out element, and
at least one cable guide, to be connected to the pull-out guide, which is designed to guide at least one power cable to the power outlet device,
wherein the pull-out guide or the pull-out element is connectable or is connected to at least one drive device, with which the drawer rail or the pull-out element to be connected thereto can be driven relative to the body rail, and the power supply device has at least one driver, which can be detachably fastened to the pull-out guide via at least one interface and is designed to cooperate with the drive device in order to transmit a force from the drive device to one of the rails of the pull-out guide or the pull-out element, wherein the cable guide and the driver form a common structural unit which can be detachably fastened to the interface of the pull-out guide.

2. The power supply device according to claim 1, wherein the drive device comprises at least one energy accumulator, preferably at least one spring device, and at least one drive element which can be driven thereby and which can be coupled to the driver, preferably wherein the drive device is designed as an ejection device in order to eject the drawer rail or the pull-out element to be connected thereto relative to the body rail from a closed position towards an open position.

3. The power supply device according to claim 1, wherein the interface is arranged on an underside of the body rail facing downwards in the position of use of the pull-out guide and/or has at least one locking device and/or a suspension device with which the common structural unit can be locked and/or suspended on the pull-out guide.

4. The power supply device according to claim 1, wherein the driver comprises at least one protruding pin or bolt which can be inserted into an opening of the drive device.

5. The power supply device according to claim 1, wherein the common structural unit comprises a substantially flat holding plate which is connectable or connected to the driver, the cable guide and/or the interface of the pull-out guide.

6. The power supply device according to claim 1, wherein the cable guide includes:
at least one groove into which the at least one power cable to be guided can be inserted, and/or
at least one deflection device which deflects the at least one power cable to be guided by at least 90°.

7. The power supply device according to claim 1, wherein at least one current conducting device is provided, which is designed to be fastened to and/or in an opening in a base of the pull-out element which is horizontally aligned in the position of use of the pull-out element and to conduct current through the base opening to the power outlet device.

8. The power supply device according to claim 1, wherein at least one holding device is provided, which is designed to hold the power outlet device on and/or in and/or above an opening in a base of the pull-out element, which is horizontally aligned in the position of use of the pull-out element.

9. The power supply device according to claim 1, wherein the power supply device further comprises:
at least one cable holder which can be detachably and/or frontally connected to the body rail, and/or
at least one drag chain which is designed to guide the at least one power cable during a movement of the pull-out element between a closed position and an open position in a plane below the pull-out element, and/or
at least one stationary plug-in device, preferably arranged on the body rail, via which the power supply device can be connected to a stationary power source, and/or
at least one switch-off device, which has at least one sensor for detecting a closed position of the pull-out guide or of the pull-out element and at least one switching element, with which the power supply can be interrupted as a function of a signal from the sensor.

10. An arrangement with at least one pull-out element, preferably a drawer or a tray, and the power supply device according to claim 1, wherein the pull-out element is connected in a position of use, preferably on a longitudinal side, to the drawer rail of the at least one pull-out guide.

11. A method for mounting the arrangement according to claim 10, on at least one furniture body, wherein the method comprises the following method steps, preferably in the specified chronological order:
mounting the at least one pull-out guide on the furniture body via the body rail,
detachably attaching the at least one driver and the at least one cable guide to the interface of the pull-out guide,
optionally, connecting at least one drive device to the pull-out guide or the pull-out element,
connecting the at least one power outlet device to the pull-out element, and
connecting the at least one pull-out element to the drawer rail of the pull-out guide.
